(19) United States
(12) Patent Application Publication
(10) Pub. No.: US 2007/0008807 A1
(43) Pub. Date: Jan. 11, 2007

(54) Wordline driver

(76) Inventor: In-Chul Jeong, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/482,209

(22) Filed: Jul. 7, 2006

(30) Foreign Application Priority Data
Jul. 7, 2005 (KR) 10-2005-61239

(51) Int. Cl. G11C 8/00; G11C 7/00; G11C 5/14

(52) U.S. Cl. 365/230.06; 365/189.11; 365/227

(57) ABSTRACT

The present invention describes systems and method for driving wordlines of memory devices. Some embodiments include a selection signal driver to generate a selection signal responsive to a first wordline signal, a main wordline driver to generate a main wordline signal responsive to a second wordline signal, the selection signal corresponding to one of the power supply voltage and the ground voltage and the main wordline signal corresponding to the other one of the power supply voltage and the ground voltage, and a sub-wordline driver to generate a sub-wordline signal responsive to the main wordline signal, the sub-wordline signal having a voltage level corresponding to the selection signal or a low voltage.

This application claims priority from Korean Patent Application No. 10-2005-61239, filed on 7 Jul. 2005, which we incorporate by reference.

### BACKGROUND OF THE INVENTION

1. Field of the Invention

The present invention relates to a semiconductor memory device, and more particularly, to wordline drivers for driving wordlines coupled to memory cells in the semiconductor memory device.

2. Description of the Related Art

Wordline drivers are circuits for enabling wordlines corresponding to predetermined row addresses.

FIG. 1 is a circuit diagram of a conventional wordline driver 10. Referring to FIG. 1, the conventional wordline driver 10 includes a plurality of level converters 11 and 13, and a driver 15. The level converter 11 receives a first wordline signal PXB from a row decoder (not shown) and generates a first converted signal by inverting and then level-shifting the first wordline signal PXB. The level converter 13 receives a second wordline signal NXB from the row decoder and generates a second converted signal by inverting and then level-shifting the second wordline signal NXB.

The first and second wordline signals PXB and NXB have voltage levels corresponding to a power supply voltage VPP and a ground VSS, while the first and second converted signals have voltage levels corresponding to the power supply voltage VPP and a low voltage VSSW. The low voltage VSSW is a negative voltage that is lower than the ground VSS. A low voltage generation circuit (not shown) generates the low voltage VSSW from an external power supply voltage and provides the low voltage VSSW to the conventional wordline driver 10.

The driver 15 generates a wordline signal WL responsive to the first and second converted signals. The wordline signal WL may have voltage levels that correspond to the power supply voltage VPP and a low voltage VSSW. When the wordline corresponding to the conventional wordline driver 10 is chosen to be enabled in response to a predetermined row address, the first wordline signal PXB is set to a logically low level or the ground VSS, and the second wordline signal NXB becomes logically high or set to the power supply voltage VPP. In this case, a PMOS transistor P1 of the sub-wordline driver 15 is turned on, and an NMOS transistor N1 of the sub-wordline driver 15 is turned off, and therefore the wordline signal WL for enabling a wordline is generated at a logically high level corresponding to the power supply voltage VPP.

When the wordline corresponding to the conventional wordline driver 10 is not chosen, the first wordline signal PXB is set to a logically high level or the power supply voltage VPP, and the second wordline signal NXB becomes a logical low or the ground VSS. Thus the wordline signal WL is generated at a logical low level corresponding to the low voltage VSSW, disabling the wordline. The level converters 11 and 13 are designed to shift the voltage level of the first and second wordline signals PXB and NXB from the ground VSS to the low voltage VSSW prior to providing the converted signals to the driver 15.

Although the use of the level converters 11 and 13 allows the conventional wordline driver 10 to disable the wordline with a low voltage VSSW, their inclusion increases the size of the conventional wordline driver 10 and thus lowers the area efficiency of a memory device. In addition, the conventional wordline driver 10 must drive a voltage pump circuit in order to maintain a negative voltage. Since the efficiency of a typical voltage pump circuit is relatively low, more current than the conventional wordline driver 10 theoretically needs must be provided to the conventional wordline driver 10 from an external current source. Thus, the more devices within the conventional wordline driver 10 in need of negative voltage from the voltage pump circuit, the higher the power consumption and inefficiency of the memory device.

### SUMMARY OF THE INVENTION

Embodiments of the present invention provide a wordline driver for a semiconductor memory device to enhance the area efficiency and reduce the current consumption of the semiconductor memory device by reducing the number of circuits that operate at a negative potential.

In some embodiments a system comprises a selection signal driver to generate a selection signal responsive to a first wordline signal, a main wordline driver to generate a main wordline signal responsive to a second wordline signal, the selection signal corresponding to one of the power supply voltage and the ground voltage and the main wordline signal corresponding to the other one of the power supply voltage and the ground voltage, and a sub-wordline driver to generate a sub-wordline signal responsive to the main wordline signal, the sub-wordline signal having a voltage level corresponding to the selection signal or a low voltage.

In some embodiments a system comprises a plurality of driver circuits to generate first and second internal signals responsive to a corresponding plurality of wordline signals, the first internal signal corresponding to a power supply voltage and the second internal signal corresponding to a ground voltage, and a sub-wordline driver to generate a sub-wordline signal responsive to the first and second internal signals, the sub-wordline signal to activate a wordline coupled to one or more memory cells with a voltage level that corresponds to the power supply voltage and to disable the wordline with a voltage level that corresponds to a low voltage.

In some embodiments a method comprises generating a selection signal responsive to a first wordline signal, generating a main wordline signal responsive to a second wordline signal, the selection signal corresponding to one of the power supply voltage and the ground-voltage and the main wordline signal corresponding to the other one of the power supply voltage and the ground voltage, and generating a sub-wordline signal responsive to the main wordline signal, the sub-wordline signal having a voltage level corresponding to the selection signal or a low voltage.

### BRIEF DESCRIPTION OF THE DRAWINGS

The features and advantages of the present invention will become more apparent with a detailed description of the exemplary embodiments referencing the attached drawings.

FIG. 1 is a circuit diagram of a conventional wordline driver.

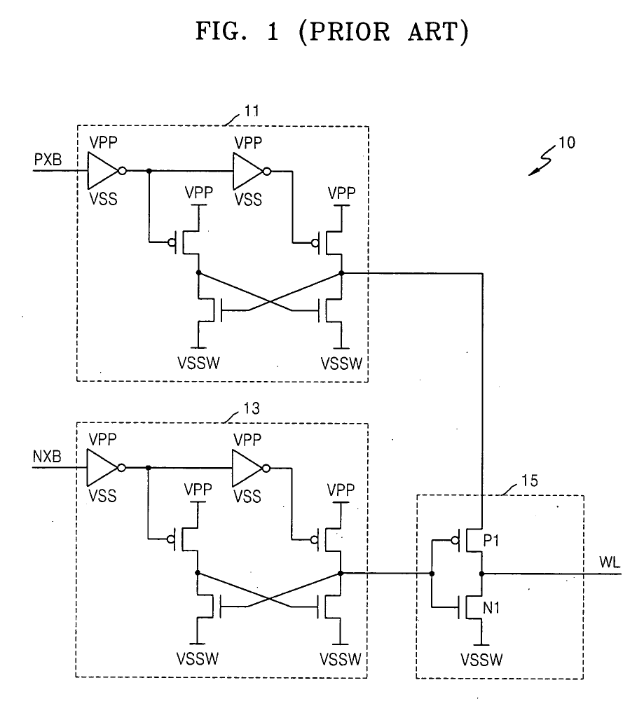

FIG. 2 is a block diagram of a wordline driver according to an exemplary embodiment of the present invention.

FIG. 3 is a circuit diagram of a wordline driver according to an exemplary embodiment of the present invention.

FIG. 4 is a diagram illustrating operational embodiments of a sub-wordline driver shown in FIG. 3.

FIG. 5 is a circuit diagram of a wordline driver according to another exemplary embodiment of the present invention.

FIG. 6 is a circuit diagram of a wordline driver according to another exemplary embodiment of the present invention.

FIG. 7 is a circuit diagram of a wordline driver according to another exemplary embodiment of the present invention.

### DETAILED DESCRIPTION OF THE INVENTION

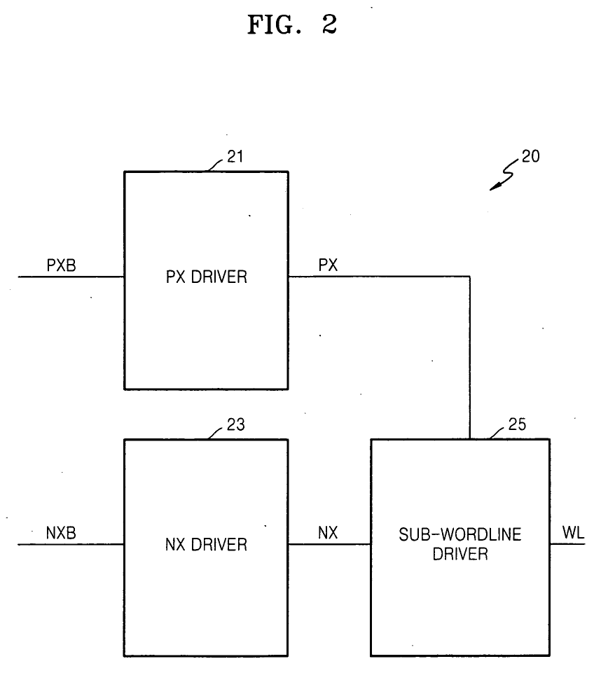

FIG. 2 is a block diagram of a wordline driver 20 according to an exemplary embodiment of the present invention. Referring to FIG. 2, the wordline driver 20 includes a PX driver (or a selection signal driver) 21, an NX driver (or a main wordline driver) 23, and a sub-wordline driver 25. The PX driver 21 receives a first wordline signal PXB from a row decoder (not shown) and outputs a selection signal PX. The selection signal PX may have a voltage level between a power supply voltage VPP and a ground voltage VSS. The NX driver 23 receives a second wordline signal NXB from the row decoder and outputs a main wordline signal NX. The main wordline signal NX may have a voltage level between the power supply voltage VPP and the ground voltage VSS. The PX driver 21 and the NX driver 23 may receive a power supply voltage VPP and a ground voltage VSS from one or more sources external to the wordline driver 20. The selection signal PX and the main wordline signal NX may be complementary internal signals, where one of the internal signals corresponds to the power supply voltage VPP and other internal signal corresponds to the ground voltage VSS.

The sub-wordline driver 25 generates a sub-wordline signal WL in response to the selection signal PX and the main wordline signal NX. The sub-wordline signal WL may have a voltage level between the selection signal PX and a low voltage VSSW. The sub-wordline signal WL may be applied to a wordline corresponding to the wordline driver 20.

The sub-wordline driver 25 generates the wordline signal WL responsive to selection signal PX and main wordline signal NX having voltage levels corresponding to the power supply voltage VPP and the ground voltage VSS instead of the low voltage VSSW. Therefore, the wordline driver 20 does not need to shift the voltage levels of the first and second wordline signals PXB and NXB to the low voltage VSSW. By eliminating this voltage level shifting, the wordline driver 20 may increase the area efficiency and reduce current consumption.

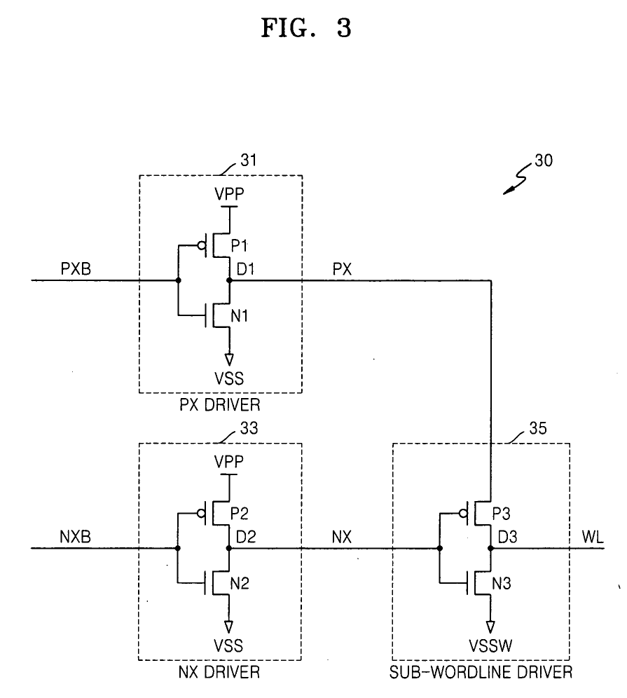

FIG. 3 is a circuit diagram of a wordline driver 30 according to an exemplary embodiment of the present invention. Referring to FIG. 3, the wordline driver 30 includes a PX driver 31, an NX driver 33, and a sub-wordline driver 35. The PX driver 31 may be an inverter circuit comprising a first PMOS transistor P1 and a first NMOS transistor N1. The first PMOS transistor P1 may be coupled between a power supply voltage VPP and a first node D1, and a first wordline signal PXB may be applied to the gate of the first PMOS transistor P1. The first NMOS transistor N1 is coupled between the first node D1 and a ground voltage VSS, and the first wordline signal PXB may be applied to the gate of the first NMOS transistor N1. A selection signal PX may be output through the first node D1 responsive to the first wordline signal PXB.

The NX driver 33 may be an inverter circuit comprising a second PMOS transistor P2 and a second NMOS transistor N2. The second PMOS transistor P2 is coupled between the power supply voltage VPP and a second node D2, and a second wordline signal NXB may be applied to the gate of the second PMOS transistor P2. The second NMOS transistor N2 is coupled between the second node D2 and the ground voltage VSS, and the second wordline signal NXB may be applied to the gate of the second NMOS transistor N2. A main wordline signal NX may be output through the second node D2 responsive to the second wordline signal NXB. In other words, the PX driver 31 and the NX driver 33 may use the power supply voltage VPP as a high-potential power supply voltage and the ground voltage VSS as a low-potential supply voltage in the respective generation of the selection signal PX and the main wordline signal NX.

The sub-wordline driver 35 may be an inverter circuit comprising a third PMOS transistor P3 and a third NMOS transistor N3. The third PMOS transistor P3 is coupled between the first node D1 and a third node D3, and the main wordline signal NX may be applied to the gate of the third PMOS transistor P3. The third NMOS transistor N3 is coupled between the third node D3 and a low voltage VSSW, and the main wordline signal NX may be applied to the gate of the third NMOS transistor N3. An output of the third node D3 may be a sub-wordline signal WL.

The operation of the wordline driver 30 will now be described with reference to FIG. 3. When a row decoder (not shown) applies a logic-high first wordline signal PXB and a logic-low second wordline signal NXB, the PX driver 31 generates a selection signal PX with a voltage level corresponding to the ground voltage VSS and the NX driver generates a main wordline signal NX with a voltage level corresponding to the power supply voltage VPP. The sub-wordline driver 35 then generates the sub-wordline signal WL corresponding to a low voltage VSSW responsive to the selection signal PX and the main wordline signal NX.

Specifically, the PX driver 31 turns off the first PMOS transistor P1 and turns on the first NMOS transistor N1 responsive to the first wordline signal PXB. Thus, the PX driver 31 generates a selection signal PX with a voltage level corresponding to the ground voltage VSS. The NX driver 33 turns on the second PMOS transistor P2 and turns off the second NMOS transistor N2 responsive to the second wordline signal NX. Thus, the NX driver 33 generates a main wordline signal NX with a voltage level corresponding to the power supply voltage VPP. The sub-wordline driver 35 turns off the third PMOS transistor P3 and turns on the third NMOS transistor N3 responsive to the selection signal PX and the main wordline signal NX. The sub-wordline driver 35 generates the sub-wordline signal WL with a voltage level corresponding to the low voltage VSSW, thus disabling a wordline corresponding to the sub-wordline signal WL or placing the wordline on standby.

Conversely, when the row decoder applies a logic-low first wordline signal PXB and a logic-high second wordline signal NXB, the PX driver 31 generates a selection signal PX with a voltage level corresponding to the power supply voltage VPP and the NX driver 33 generates a main wordline signal NX with a voltage level corresponding to the ground voltage VSS. The sub-wordline driver 35 generates the sub-wordline signal WL corresponding to the power supply voltage VPP responsive to the selection signal PX and the main wordline signal NX.

Specifically, the PX driver 31 turns on the first PMOS transistor P1 and turns off the first NMOS transistor N1 responsive to the first wordline signal PXB. Thus, the PX driver 31 generates a selection signal PX with a voltage level corresponding to the power supply voltage VPP. The NX driver 33 turns off the second PMOS transistor P2 and turns on the second NMOS transistor N2 responsive to the first second wordline signal NXB. Thus, the NX driver 33 generates a main wordline signal NX with a voltage level corresponding to the ground VSS. The sub-wordline driver 35 turns on the third PMOS transistor P3 and turns off the third NMOS transistor N3 responsive to the selection signal PX and the main wordline signal NX. The sub-wordline driver 35 generates the sub-wordline signal WL with a voltage level corresponding to power supply voltage VPP, thus enabling a wordline corresponding to the sub-wordline signal WL or placing the wordline in an active mode.

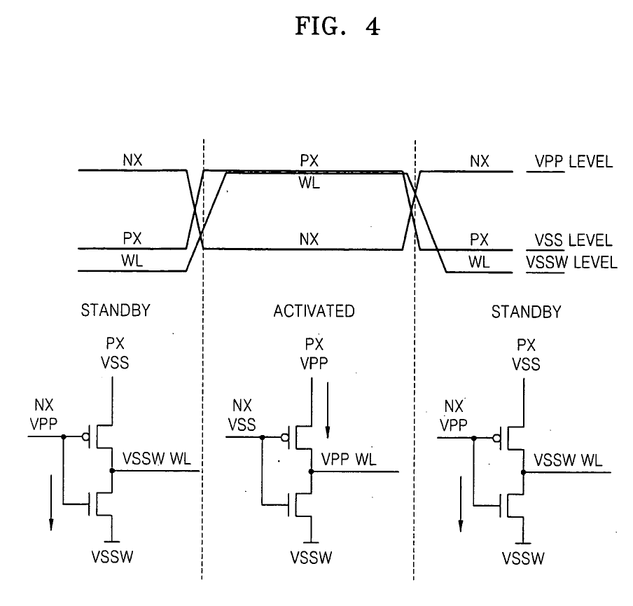

FIG. 4 is a diagram illustrating operational embodiments of a sub-wordline driver 35 shown in FIG. 3. Referring to FIG. 4, when a wordline is on standby (or disabled), the sub-wordline signal WL may correspond to the low voltage VSSW. The voltage level of a main wordline signal NX may correspond to the power supply voltage VPP, and the selection signal PX may correspond to the ground voltage VSS. On the other hand, when the wordline is activated (or enabled), the sub-wordline signal WL may correspond to the power supply voltage VPP. The main wordline signal NX may correspond to the level of the ground voltage VSS, and the selection signal PX may correspond to the level of the power supply voltage VPP. The wordline signal NX and the selection signal PX may swing between the level of the power supply voltage VPP and the level of the ground voltage VSS, thus preventing additional current consumption by the wordline driver 30 (FIG. 3).

When the wordline is activated, the selection signal PX may correspond to the power supply voltage VPP, and the main wordline signal NX may correspond to the ground voltage VSS. Thus, the gate of the third NMOS transistor N3 of the sub-wordline driver 35 may receive the ground voltage VSS, while the source of the third NMOS transistor N3 receives the low voltage VSSW.

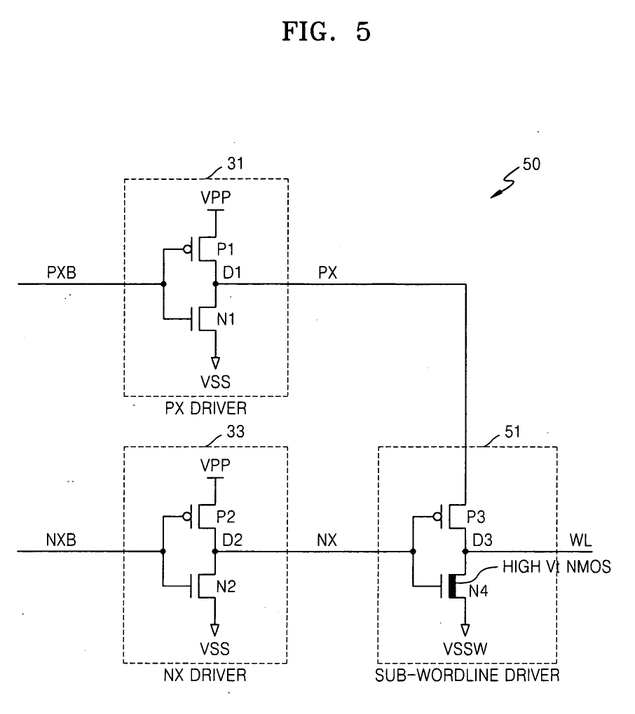

FIG. 5 is a circuit diagram of a wordline driver 50 according to another exemplary embodiment of the present invention. Referring to FIG. 5, the wordline driver 50 is similar to the wordline driver 30 of FIG. 3 with the following differences. The wordline driver 50 includes a sub-wordline driver 51 to generate a wordline signal WL responsive to a selection signal PX and a main wordline signal NX. The sub-wordline driver 51 may be an inverter circuit comprising a third PMOS transistor P3 and a fourth NMOS transistor N4. The fourth NMOS transistor N4 is coupled between the third PMOS transistor P3 and a low voltage VSSW.

The fourth NMOS transistor N4 may have a relatively high threshold voltage Vt as compared to other transistors included in the wordline driver 50. This increased threshold voltage Vt may prevent or reduce the generation of a leakage current when a wordline is activated. The leakage current may be generated when a gate-to-source voltage Vgs of the fourth transistor N4 is greater than the threshold voltage Vt. Since during wordline activation, a ground voltage VSS is applied to the gate of the fourth NMOS transistor N4 and a low voltage VSSW is applied to the source, the gate-to-source voltage Vgs corresponding to the fourth NMOS transistor N4 is positive. In some embodiments of the present invention, the high threshold voltage Vt of the fourth NMOS transistor N4 may be greater than or substantially equal to this gate-to-source voltage Vgs, and thus prevent or reduce the generation of the leakage current.

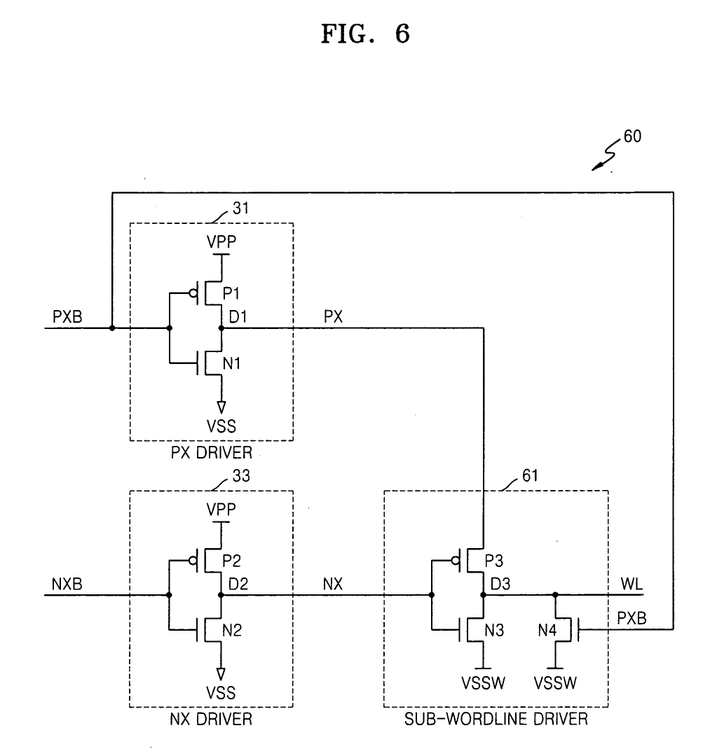

FIG. 6 is a circuit diagram of a wordline driver 60 according to another exemplary embodiment of the present invention. Referring to FIG. 6, the wordline driver 60 includes a PX driver 31, an NX driver 33, and a sub-wordline driver 61. The PX driver 31 and the NX driver 33 may be similar to their respective counterparts illustrated in FIG. 3 or 5. The sub-wordline driver 61 includes a third PMOS transistor P3 and a third NMOS transistor N3 whose gates receive a main wordline signal NX. The sub-wordline driver 61 additionally includes a fourth NMOS transistor N4 with a gate that receives the first wordline signal PXB from a row decoder (not shown).

The third PMOS transistor P3 is coupled between a first node D1 and a third node D3, and the main wordline signal NX is applied to the gate of the third PMOS transistor P3. The third NMOS transistor N3 is coupled between the third node D3 and a low voltage VSSW, and the main wordline signal NX is applied to the gate of the third NMOS transistor N3. The fourth NMOS transistor N4 is coupled between the third node D3 and the low voltage VSSW, and the first wordline signal PXB is applied to the gate of the fourth NMOS transistor N4.

When a wordline is disabled, the level of the main wordline signal NX may correspond to the power supply voltage VPP, the selection signal PX may correspond to the level of a ground VSS, and the first wordline signal PXB may correspond to the power supply voltage VPP. Thus, the third PMOS transistor P3 is turned off, the third NMOS transistor N3 is turned on, and the level of the sub-wordline signal WL corresponds to the low voltage VSSW. The fourth NMOS transistor N4 is turned on responsive to the first wordline signal PXB, thus preventing the disabled wordline from floating.

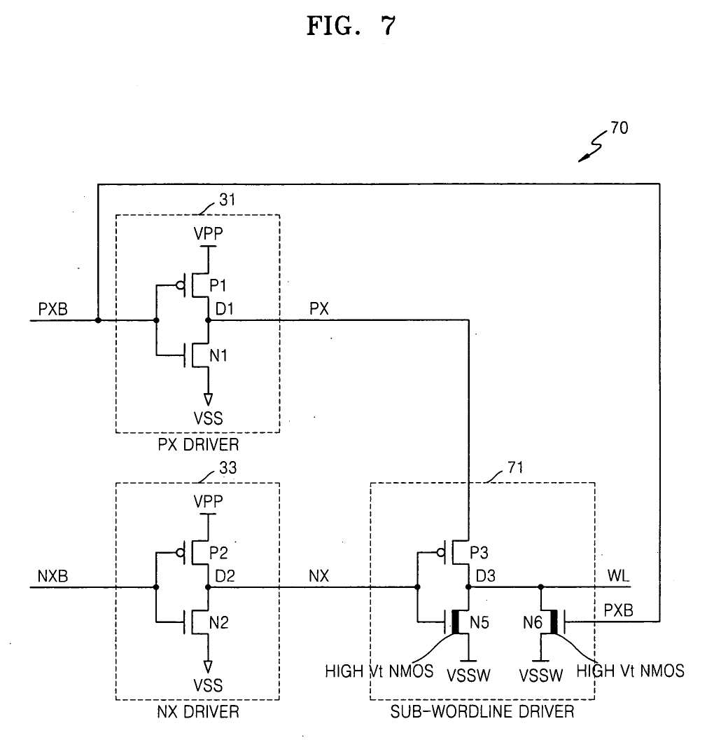

FIG. 7 is a circuit diagram of a wordline driver 70 according to another exemplary embodiment of the present invention. Referring to FIG. 7, the wordline driver 70 may be similar to wordline driver 60 of FIG. 6 with the following differences. The wordline driver 70 includes a sub-wordline driver 71 to generate a wordline signal WL responsive to the selection signal PX and the main wordline signal NX.

The sub-wordline driver 71 includes fifth and sixth NMOS transistors N5 and N6 with threshold voltages Vt higher than the threshold voltages of the third and fourth NMOS transistors N3 and N4 of FIG. 6. As similarly discussed above with reference to FIG. 5, the high threshold voltage Vt in the fifth and sixth NMOS transistors N5 and N6 may prevent or reduce the generation of a leakage current during wordline activation.

As described above, according to the present invention, the number of circuits using a negative voltage can be minimized. Thus, the wordline driver according to the present invention does not need to serve as a negative charge pump for generating a negative voltage, thereby reducing the current consumption of a memory device. Accordingly, the wordline driver according to the present invention can reduce the amount of power used for enabling a wordline.

While the present invention has been particularly shown and described with reference to exemplary embodiments thereof, it will be understood by those of ordinary skill in the art that various changes in form and details may be made therein without departing from the spirit and scope of the present invention as defined by the following claims.

I claim the following:

1. A system comprising:
a selection signal driver to generate a selection signal responsive to a first wordline signal;
a main wordline driver to generate a main wordline signal responsive to a second wordline signal, the selection signal swinging between a power supply voltage and a ground voltage and the main wordline signal swinging between the power supply voltage and the ground voltage; and
a sub-wordline driver to generate a sub-wordline signal responsive to the main wordline signal, the sub-wordline signal swinging between the voltage level of the selection signal and a low voltage.

2. The system of claim 1 where the selection signal is corresponding to one of the power supply voltage and the ground voltage and the main wordline signal is corresponding to the other one of the power supply voltage and the ground voltage; and
the sub-wordline signal has the voltage level corresponding to the selection signal or the low voltage.

3. The system of claim 1 where the low voltage is lower than the power supply voltage and the ground voltage.

4. The system of claim 1 where the selection signal driver, the main wordline driver, and the sub-wordline driver are inverters.

5. The system of claim 1 where the sub-wordline driver includes
a first transistor having a gate to receive the main wordline signal and a first terminal to receive the selection signal; and
a second transistor having a gate to receive the main wordline signal and a first terminal to receive the low voltage, where second terminals of the first and second transistors output the sub-wordline signal.

6. The system of claim 5 where the second transistor has a threshold voltage that is greater than or equal to threshold voltages of other transistors included in the system.

7. The system of claim 5 where the second transistor has a threshold voltage that is greater than or equal to the difference between the ground voltage and the low voltage.

8. The system of claim 5 including a third transistor having a gate to receive the first wordline signal and a first terminal to receive the low voltage, where a second terminal of the third transistor is coupled to the first and second transistors.

9. The system of claim 8 where the third transistor has a threshold voltage that is greater than or equal to threshold voltages of other transistors included in the system.

10. The system of claim 8 where the third transistor has a threshold voltage that is greater than or equal to the difference between the ground voltage and the low voltage.

11. The system of claim 1 where the selection signal driver includes
a third transistor which is connected between the power supply voltage and a first node and has a gate to which the first wordline signal is applied; and
a fourth transistor which is connected between the first node and the ground voltage and has a gate to which the first wordline signal is applied,
where an output of the first node is the selection signal.

12. The system of claim 1 where the main wordline driver includes
a fifth transistor which is connected between the power supply voltage and a second node and has a gate to which the second wordline signal is applied; and
a sixth transistor which is connected between the second node and the ground voltage and has a gate to which the second wordline signal is applied,
where an output of the second node is the main wordline signal.

13. The system of claim 1 where the system is a wordline driver.

14. A system comprising:
a plurality of driver circuits to generate first and second internal signals responsive to a corresponding plurality of wordline signals, the first internal signal and the second internal signal swinging between a power supply voltage and a ground voltage; and
a sub-wordline driver to generate a sub-wordline signal responsive to the first and second internal signals, the sub-wordline signal to activate a wordline coupled to one or more memory cells with a voltage level that corresponds to the power supply voltage and to disable the wordline with a voltage level that corresponds to a low voltage.

15. The system of claim 14 where the first internal signal corresponding to the power supply voltage and the second internal signal corresponding to the ground voltage.

16. The system of claim 14 where the low voltage is lower than the power supply voltage and the ground voltage.

17. The system of claim 14 where the plurality of driver circuits includes
a selection signal driver to generate a selection signal responsive to a first wordline signal; and
a main wordline driver to generate a main wordline signal responsive to a second wordline signal, the selection signal corresponding to one of the power supply voltage and the ground voltage and the main wordline signal corresponding to the other one of the power supply voltage and the ground voltage.

18. The system of claim 17 where the selection signal corresponds to the first internal signal and the main wordline signal corresponds to the second internal signal.

19. The system of claim 17 where the main wordline signal corresponds to the first internal signal and the selection signal corresponds to the second internal signal.

20. The system of claim 14 where the sub-wordline driver generates the sub-wordline signal responsive to the first and second internal signals and a first wordline signal.

21. A method comprising:
generating a selection signal responsive to a first wordline signal;
generating a main wordline signal responsive to a second wordline signal, the selection signal swinging between a power supply voltage and a ground voltage and the main wordline signal swinging between the power supply voltage and the ground voltage; and
generating a sub-wordline signal responsive to the main wordline signal, the sub-wordline signal swinging between the voltage level of the selection signal and a low voltage.

22. The method of claim 21 where the selection signal is corresponding to one of the power supply voltage and the ground voltage and the main wordline signal is corresponding to the other one of the power supply voltage and the ground voltage; and
the sub-wordline signal has the voltage level corresponding to the selection signal or the low voltage.

23. The method of claim 21 where the low voltage is lower than the power supply voltage and the ground voltage.

24. The method of claim 21 includes generating a sub-wordline signal responsive to the main wordline signal and the first wordline signal.
